(19) United States
(12) Patent Application Publication
(10) Pub. No.: US 2005/0237717 A1
(43) Pub. Date: Oct. 27, 2005

(54) Method and apparatus for reducing acoustic noise from paired cooling fans

(76) Inventors: Samuel Martin Babb, Fort Collins, CO (US); Jeffrey S. Weaver, Fort Collins, CO (US); Peter Piotrowski, Fort Collins, CO (US); Garland Lee, Windsor, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/830,660

(22) Filed: Apr. 22, 2004

(51) Int. Cl. H05K 7/20

(52) U.S. Cl. 361/697

(57) ABSTRACT

A pair of cooling fans in an electronic system is operated synchronously at a common speed and with a particular phase relationship between their respective acoustic properties that minimizes the combined acoustic noise produced by the pair of cooling fans.

### FIELD OF THE INVENTION

The present invention relates generally to electronic systems and more specifically to techniques for cooling electronic systems.

### BACKGROUND OF THE INVENTION

Cooling an electronic system to maintain an acceptable operating temperature is important in many applications. Cooling is often accomplished by the use of cooling fans. For example, a heat-sink fan may be used to cool a particular component, and a system fan may be used to cool a particular thermal zone generally within the electronic system. In some applications, such cooling fans are deployed in pairs, the two cooling fans being in relatively close proximity. Both heat-sink fans and system fans may be deployed in paired fashion.

Acoustic noise from cooling fans is a common complaint among users of electronic systems such as desktop personal computers (PCs) and workstations. The problem is especially bothersome where multiple PCs or workstations are used in close proximity, as is often the case in research and development organizations. The problem is further exacerbated when the electronic systems include multiple cooling fans, as in the paired-cooling-fan configuration just described.

It is thus apparent that there is a need in the art for an improved method and apparatus for reducing acoustic noise from paired cooling fans.

### SUMMARY OF THE INVENTION

A method for minimizing the acoustic noise produced by a first cooling fan and a second cooling fan in an electronic system is provided. An apparatus for carrying out the method is also provided.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is an illustration of an electronic system in accordance with an illustrative embodiment of the invention.

FIG. 2A is an illustration showing acoustic properties associated with a pair of cooling fans in accordance with an illustrative embodiment of the invention.

FIG. 2B is an illustration showing destructive interference between the acoustic properties shown in FIG. 2A when a particular phase relationship has been achieved between them in accordance with an illustrative embodiment of the invention.

FIG. 2C is an illustration of tachometer signals associated with a pair of cooling fans in accordance with an illustrative embodiment of the invention.

FIG. 3 is a block diagram of an open-loop drive circuit in accordance with an illustrative embodiment of the invention.

FIG. 4 is a block diagram of a closed-loop drive circuit in accordance with an illustrative embodiment of the invention.

FIG. 5 is a block diagram of a closed-loop drive circuit in accordance with another illustrative embodiment of the invention.

FIG. 6 is a flowchart of a method for minimizing the acoustic noise produced by a pair of cooling fans in accordance with another illustrative embodiment of the invention.

### DETAILED DESCRIPTION OF THE INVENTION

Acoustic noise produced by a pair of cooling fans may be minimized by operating the cooling fans synchronously (at the same speed and in the same direction) but with a phase relationship between their acoustic properties (“particular phase relationship”) that minimizes the combined acoustic noise produced by the pair of cooling fans. This technique exploits the largely periodic nature of the acoustic noise produced by a typical cooling fan. The periodicity results from, for example, fan blades passing the struts of the fan housing and motor poles passing magnets. When two cooling fans in relatively close proximity are operated with the correct rotational offset (difference between the positions of corresponding fan blades of the two cooling fans relative to a fixed reference point as they rotate synchronously), the corresponding acoustic waveforms destructively interfere, minimizing the combined acoustic noise. When this technique is not employed, the acoustic noise of the two cooling fans may even constructively interfere, worsening the environmental noise problem for a user.

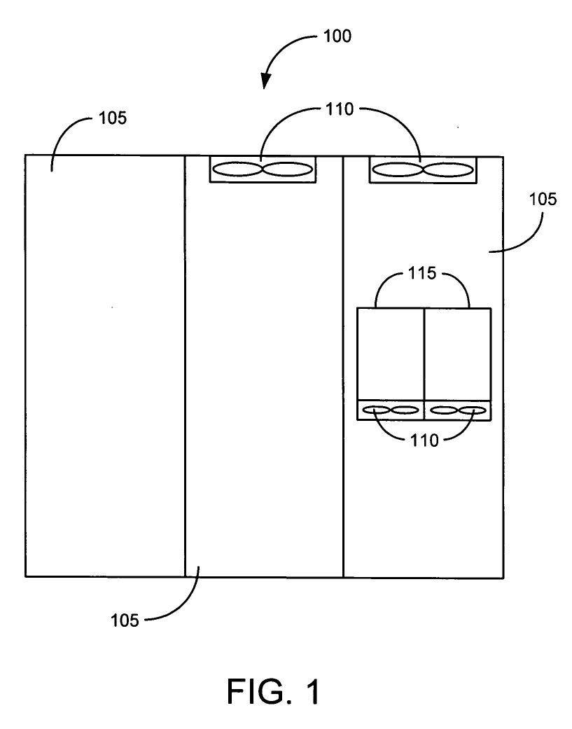

FIG. 1 is an illustration of an electronic system 100 in accordance with an illustrative embodiment of the invention. Electronic system 100 may be a desktop computer, notebook computer, workstation, server, or any other electronic system that employs cooling fans. Electronic system 100 may have one or more thermal zones 105, which may be partitioned in some applications. A given thermal zone 105 may be cooled using cooling fans 110. FIG. 1 illustrates both paired system fans (top of FIG. 1) and paired heat-sink fans (near electronic components 115). The principles of the invention may be applied to either type of paired cooling fans 110. The acoustic noise reduction achieved is generally greatest when paired cooling fans 110 are in close proximity because the destructive-interference between the acoustic outputs of the two cooling fans 100 is more pronounced in such a configuration.

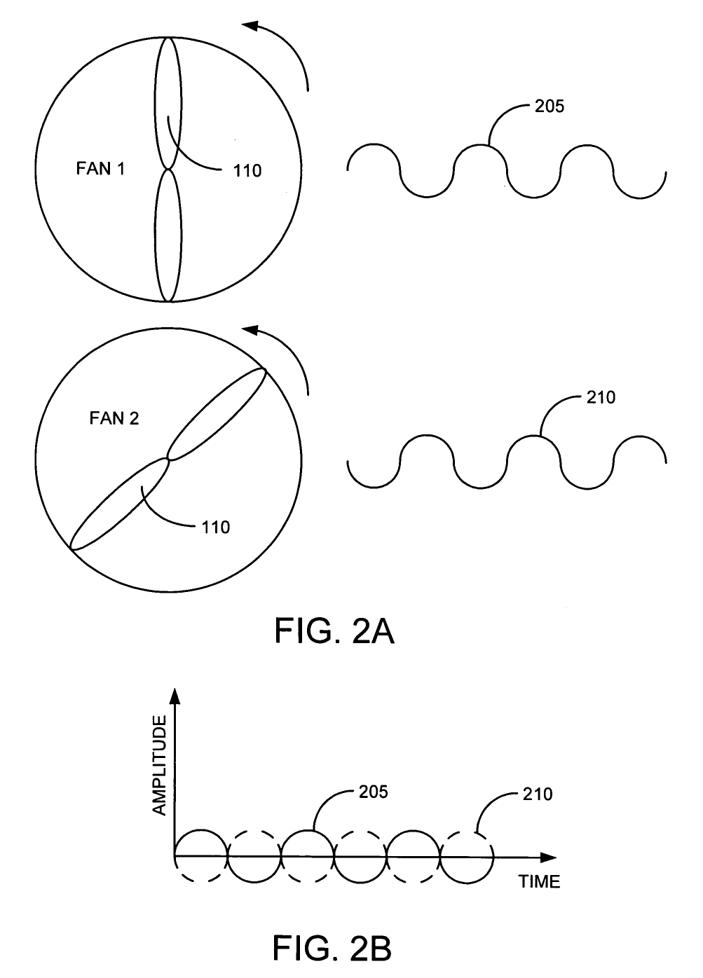

FIG. 2A is an illustration showing acoustic properties associated with a pair of cooling fans 110 in accordance with an illustrative embodiment of the invention. For convenience in describing FIG. 2A, the two cooling fans 110 have been arbitrarily labeled “Fan 1” and “Fan 2.” Each cooling fan 110 produces acoustic noise that is significantly periodic in nature. Fan 1 has associated acoustic properties 205 (e.g., an acoustic noise waveform), and Fan 2 has associated acoustic properties 210. Acoustic properties 205 and 210, though they may have significant periodic content, are not necessarily sinusoidal. Acoustic properties 205 and 210 combine to produce the combined acoustic noise from Fan 1 and Fan 2. Waveforms 205 and 210 may constructively interfere (add) or destructively interfere (subtract). If the rotational offset between Fan 1 and Fan 2 is properly chosen, acoustic properties 205 and 210 destructively interfere, as illustrated in FIG. 2B, minimizing the combined acoustic noise. FIG. 2B is somewhat idealized in that a phase difference (particular phase relationship) of 180 degrees between acoustic properties 205 and 210 is not necessarily the optimum choice in practice, and actual acoustic properties 205 and 210 are more complex and irregular than those illustrated. The goal is not necessarily to cancel the acoustic noise. Outright cancellation is generally not possible because of differences between acoustic properties 205 and 210 and non-periodic noise components in the two waveforms. Rather, the objective is to minimize the combined acoustic noise by the choice of an appropriate phase difference between acoustic properties 205 and 210.

Determining the particular phase relationship may be accomplished in several different ways. One of the simplest, a deterministic approach, is to consider the physical properties of the cooling fans 110 in choosing the rotational offset between the two cooling fans 110. Those skilled in the art will recognize that it is possible to predict the phase difference between the acoustic properties 205 and 210 associated with a pair of cooling fans 110 based on the rotational offset between the two cooling fans 110. Physical properties such as housing strut configuration, the number of motor poles, and magnets allow one skilled in the art to predict the periodicity of the acoustic properties associated with each individual cooling fan 110. Therefore, the phase relationship between acoustic properties 205 and 210 may also be predicted. In practice, the rotational offset between the blades of the two cooling fans 110 may be only a few degrees, depending on the physical properties of the cooling fans 110. The rotational offset illustrated between Fan 1 and Fan 2 in FIG. 2A has been accentuated for clarity.

The particular phase relationship may also be determined dynamically. For example, the combined acoustic noise from the two cooling fans 110 may be measured dynamically using a transducer (e.g., a microphone), and the rotational offset between the two synchronously rotating cooling fans 110 may be adjusted until the desired phase relationship between acoustic properties 205 and 210 is achieved (i.e., until the combined acoustic noise measured by the transducer is minimized). More will be said about this approach in a later portion of this detailed description.

FIG. 2C is an illustration of respective tachometer signals 215 and 220 output from a pair of cooling fans 110 in accordance with an illustrative embodiment of the invention. A cooling fan 110 may have an output tachometer signal that indicates the state of its rotation. For a typical cooling fan 110, two periods of the tachometer waveform correspond to a single rotation of cooling fan 110. Tachometer signals 215 and 220 may be used by a suitable control circuit to establish a desired rotational offset 225 between cooling fans 110. As explained above, rotational offset 225 may be chosen to achieve the particular phase relationship between acoustic properties 205 and 210 that minimizes the combined acoustic noise produced by a pair of cooling fans 110.

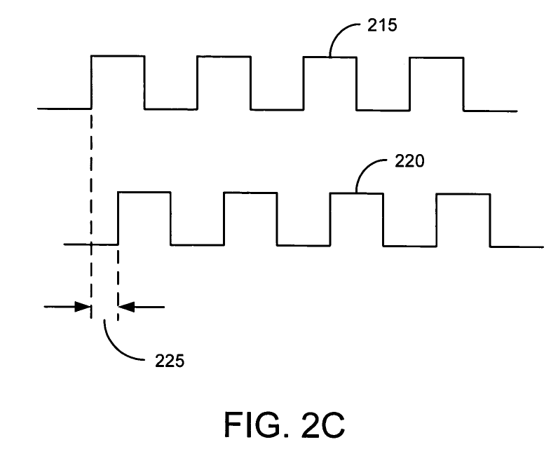

FIGS. 3-5 illustrate different types of control circuits for driving a pair of cooling fans 110 in accordance with illustrative embodiments of the invention. The control circuits shown in FIGS. 3-5 are merely examples. Many other types of fan control systems may be used, all of which are considered to be within the scope of the invention as claimed. In general, an accurate two-phase drive system may be employed in implementing the invention. Such two-phase drive systems are well known in the art and may be implemented using, for example, a three-phase motor, phase locking techniques, and other suitable techniques. Cooling fans 110 may be driven by constant voltages or by pulses spaced in time (e.g., a pulse-width-modulated signal).

FIG. 3 is a block diagram of an open-loop drive circuit 300 in accordance with an illustrative embodiment of the invention. In FIG. 305 oscillator (pulse generator) 305 outputs a signal that drives both Fan 1 and Fan 2 via drivers 310. Delay 315 in the path associated with Fan 2 establishes a rotational offset between Fan 1 and Fan 2 corresponding to the particular phase relationship, as defined above. Delay 315 may be advantageously implemented as a combination of a microprocessor or microcontroller and associated firmware, as those skilled in the art will recognize. Alternatively, an LC circuit may be used.

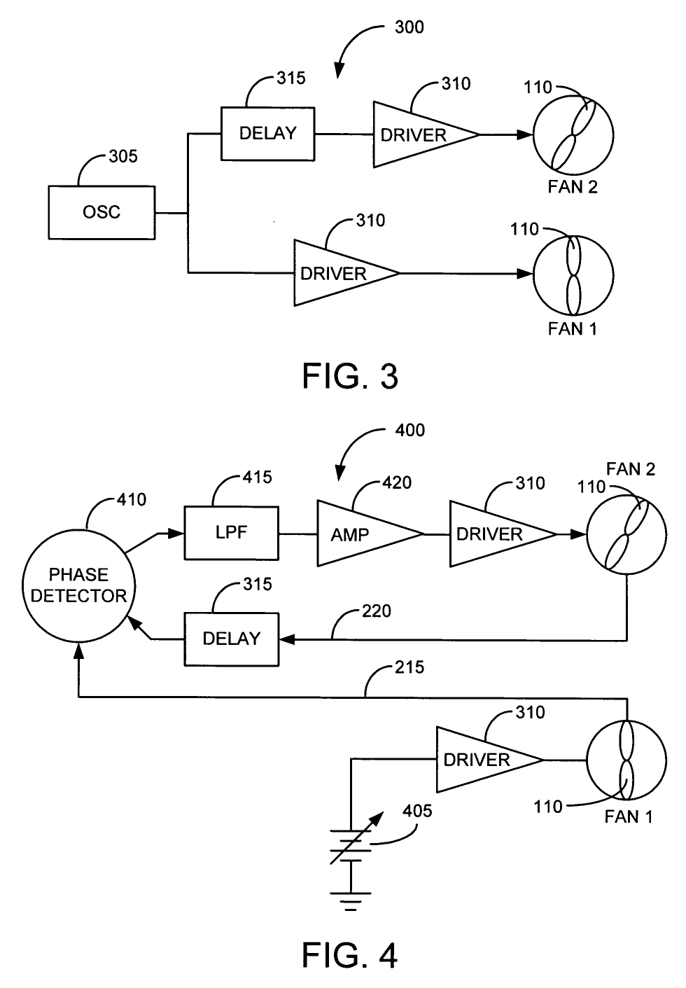

FIG. 4 is a block diagram of a closed-loop drive circuit 400 in accordance with an illustrative embodiment of the invention. In FIG. 4, Fan 1 is driven at an adjustable set point 405 through driver 310. Tachometer signal 215 from Fan 1 is fed back to phase detector 410. Tachometer signal 220 from Fan 2 is also fed back to phase detector 410 through delay 315. Phase detector 410 is configured to drive the output error signal fed to low-pass filter (LPF) 415 toward zero. Amplifier 420 provides sufficient loop gain to drive Fan 2 at a voltage that achieves the desired synchronous operation and rotational offset between the two cooling fans 110.

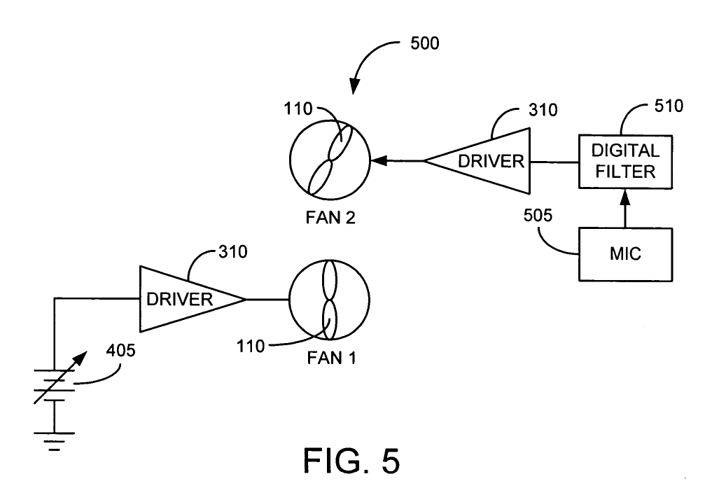

FIG. 5 is a block diagram of a closed-loop drive circuit 500 in accordance with another illustrative embodiment of the invention. In FIG. 5, the particular phase relationship is determined dynamically, as explained above. The portion of FIG. 5 that relates to Fan 1 is the same as that shown in FIG. 4. Microphone 505 dynamically measures the combined acoustic noise from Fan 1 and Fan 2. The output of microphone 505 is processed by digital filter 510, which produces a suitable drive signal for Fan 2. Digital filter 510 may adjust the rotational offset between Fan 1 and Fan 2 until the combined acoustic noise measured by microphone 505 is minimized, at which point the particular phase relationship is achieved. The embodiment shown in FIG. 5 is merely illustrative and lends itself to numerous variations. For example, other types of transducers may be used (e.g., accelerometers).

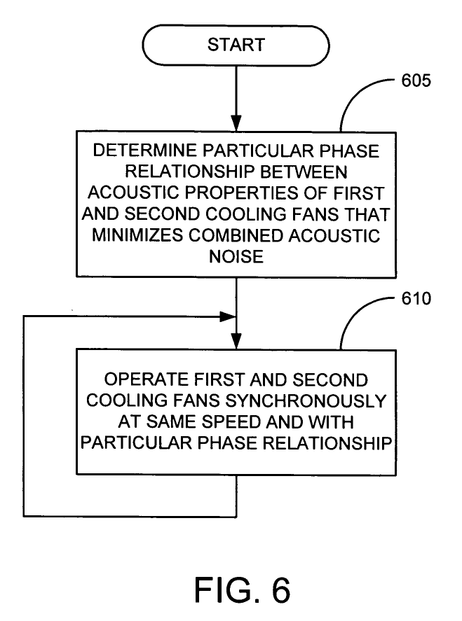

FIG. 6 is a flowchart of a method for minimizing the acoustic noise produced by a pair of cooling fans in accordance with another illustrative embodiment of the invention. At 605, the particular phase relationship between acoustic properties 205 and 210 that minimizes the combined acoustic noise produced by a pair of cooling fans 110 may be determined. In many applications, this may be done once in advance. As explained above, the particular phase relationship may be determined in a variety of ways. Once the particular phase relationship has been determined, the pair of cooling fans 110 may be operated, at 610, with the particular phase relationship by driving the cooling fans 110 with the appropriate rotational offset 225.

In some applications, it may be necessary to determine a particular phase relationship for each of several possible speeds at which cooling fans 110 are operated. That is, the particular phase relationship may vary as a function of fan speed. In such situations, it is advantageous to store the particular phase relationship associated with each speed in a lookup table. As the temperature within electronic system 100 varies, the speed of cooling fans 110 may be adjusted accordingly, and the cooling fans 110 may be driven synchronously with the particular phase relationship.

The foregoing description of the present invention has been presented for the purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A method for minimizing the acoustic noise produced by a first cooling fan and a second cooling fan in an electronic system, the first and second cooling fans each having associated acoustic properties, the method comprising:
determining a particular phase relationship between the acoustic properties of the first and second cooling fans that minimizes the combined acoustic noise produced by the first and second cooling fans; and
operating the first and second cooling fans synchronously at a common speed and with the particular phase relationship.

2. The method of claim 1, wherein the first and second cooling fans are in close proximity.

3. The method of claim 1, wherein the first and second cooling fans are heat-sink fans.

4. The method of claim 1, wherein the first and second cooling fans are system fans.

5. The method of claim 1, wherein the acoustic properties comprise acoustic waveforms associated with the first and second cooling fans, respectively.

6. The method of claim 1, wherein determining a particular phase relationship between the acoustic properties of the first and second cooling fans that minimizes the combined acoustic noise produced by the first and second cooling fans comprises deterministically choosing, based on physical properties of the first and second cooling fans, a rotational offset between the first and second cooling fans that corresponds to the particular phase relationship.

7. The method of claim 1, wherein determining a particular phase relationship between the acoustic properties of the first and second cooling fans that minimizes the combined acoustic noise produced by the first and second cooling fans comprises:
measuring dynamically a combined acoustic signal from the first and second cooling fans using a transducer; and
adjusting a rotational offset between the first and second cooling fans until the magnitude of the combined acoustic signal is minimized.

8. The method of claim 1, wherein operating the first and second cooling fans synchronously at a common speed and with the particular phase relationship is accomplished using an open-loop control circuit.

9. The method of claim 1, wherein operating the first and second cooling fans synchronously at a common speed and with the particular phase relationship is accomplished using a closed-loop control circuit.

10. The method of claim 1, wherein the particular phase relationship differs depending on the common speed at which the first and second cooling fans are operated and the particular phase relationship associated with each of a set of predetermined speeds is stored in a lookup table.

11. The method of claim 1, wherein the electronic system comprises one of a desktop computer, a notebook computer, a workstation, and a server.

12. An electronic system, comprising:
at least one component;
a first cooling fan and a second cooling fan to cool the at least one component; and
a fan control subsystem configured to operate the first and second cooling fans synchronously at a common speed and with a particular phase relationship, the particular phase relationship minimizing the combined acoustic noise produced by the first and second cooling fans.

13. The electronic system of claim 12, wherein the fan control subsystem comprises an open-loop two-phase drive circuit.

14. The electronic system of claim 12, wherein the fan control subsystem comprises a closed-loop two-phase drive circuit.

15. The electronic system of claim 14, wherein a feedback portion of the closed-loop two-phase drive circuit comprises a tachometer signal from each of the first and second cooling fans.

16. The electronic system of claim 12, wherein the first and second cooling fans are heat-sink fans.

17. The electronic system of claim 12, wherein the first and second cooling fans are system fans.

18. The electronic system of claim 12, wherein the fan control subsystem includes a transducer and the fan control subsystem is configured to measure dynamically a combined acoustic signal from the first and second cooling fans output by the transducer and to adjust a rotational offset between the first and second cooling fans until the combined acoustic signal is minimized.

19. The electronic system of claim 12, wherein the electronic system comprises one of a desktop computer, a notebook computer, a workstation, and a server.

20. An electronic system, comprising:
at least one component;
a first cooling fan and a second cooling fan to cool the at least one component; and
means for operating the first and second cooling fans synchronously at a common speed and with a particular phase relationship, the particular phase relationship minimizing the combined acoustic noise produced by the first and second cooling fans.

21. The electronic system of claim 20, wherein the means for operating the first and second cooling fans synchronously at a common speed and with a particular phase relationship comprises an open-loop two-phase drive circuit.

22. The electronic system of claim 20, wherein the means for operating the first and second cooling fans synchronously at a common speed and with a particular phase relationship comprises a closed-loop two-phase drive circuit.
